(19) United States
(12) Patent Application Publication
(10) Pub. No.: US 2007/0032096 A1
(43) Pub. Date: Feb. 8, 2007

(54) System and process for providing multiple beam sequential lateral solidification

(76) Inventor: James S. Im, New York, NY (US)

Correspondence Address: BAKER & BOTTS L.L.P., 30 ROCKEFELLER PLAZA, 44TH FLOOR, NEW YORK, NY, 10112-4498, US

(21) Appl. No.: 11/372,148

(22) Filed: Mar. 9, 2006

Related U.S. Application Data
(63) Continuation of application No. PCT/US04/30327, filed on Sep. 16, 2004.
(60) Provisional application No. 60/503,421, filed on Sep. 16, 2003.

(51) Int. Cl. H01L 21/00; H01L 21/20

(52) U.S. Cl. 438/795; 438/487; 438/799

(57) ABSTRACT

A process and system for processing a thin film on a sample are provided. In particular, a plurality of separated beams each including beam pulses are generated. At least one first beam of the separated beams is forwarded through a mask to irradiate and heat the thin film sample prior to further irradiation. At least one second beam of the separated beams is then forwarded through a mask to further irradiate the thin film sample. Additional separated beams are sent through a mask to produce and further irradiate the thin film until the combined intensity of the beams impinging on the sample is sufficient to melt a section of the thin film throughout its entire thickness.

### FIELD OF THE INVENTION

The present invention relates to techniques for processing of semiconductor films, and more particularly to techniques for processing semiconductor films using multiple patterned laser beamlets.

### BACKGROUND OF THE INVENTION

Techniques for fabricating large grained single crystal or polycrystalline silicon thin films using sequential lateral solidification (SLS) are known in the art. For example, in U.S. Pat. No. 5,285,236 (“the '236 patent”) and U.S. patent application Ser. No. 09/390,537, the entire disclosures of which are incorporated herein by reference and which has been assigned to the common assignee of the present application, particularly advantageous apparatus and methods for growing large grained polycrystalline or single crystal silicon structures using energy-controllable laser pulses and small-scale translation of a silicon sample to implement SLS have been disclosed. The SLS techniques and systems described therein provide that low defect density crystalline silicon films can be produced on those substrates that do not permit epitaxial regrowth, upon which high performance microelectronic devices can be fabricated.

Referring to FIG. 1, the '236 patent discloses a 1:1 projection irradiation system. In particular, an illumination system 20 of this projection irradiation system generates a homogenized laser beam which passes through an optical system 22, a mask 14, a projection lens and a reversing unit to be incident on a substrate sample 10. However, in this prior art projection irradiation system, the energy density on the mask 14 must be greater than the energy density on the substrate 10. When the desired processes require high fluence on the substrate 10, the high energy density incident on the mask 14 can cause physical damage to the mask 14. In addition, such high energy laser light can cause damage to the optics of the system. Accordingly, the use of dual beam irradiation for SLS processing with a 1:1 imaging scheme has been previously disclosed in U.S. patent application Ser. No. 60/253,256, the entire disclosures of which is incorporated herein by reference and which has been assigned to the common assignee of the present application. The rationale for dual-beam irradiation was to reduce the fluence of the beam passing through the mask to allow 1:1 imaging without exceeding the mask damage threshold.

In addition, International Publication No. 02/086954 describes a method and system for providing a single-scan, continuous motion sequential lateral solidification of melted sections of the sample being irradiated by beam pulses, the entire disclosure of which is incorporated herein by reference. In this publication, an accelerated sequential lateral solidification of the polycrystalline thin film semiconductors provided on a simple and continuous motion translation of the semiconductor film are achieved, without the necessity of “microtranslating” the thin film, and re-irradiating the previously irradiated region in the direction which is the same as the direction of the initial irradiation of the thin film while the sample is being continuously translated.

However, there still exists a need for an improved system for implementing the sequential lateral solidification process. Accordingly, the present invention provides a multiple beam SLS system and process that allows more control to modify the microstructure of the thin film and further optimizes the SLS process.

### SUMMARY OF THE INVENTION

One of the objects of the present invention is to provide an improved projection irradiation system and process to implement sequential lateral solidification. It is another object of the present invention is to provide a system and process to modify the microstructure of the thin film sample. It is another object of the present invention to provide a system and process where the mask utilized for shaping the laser beams and pulses is not damaged or degraded due to the intensity of the beams/pulses. It is also another object of the present invention to increase the lifetime of the optics of the system by decreasing the energy being emitted through the optical components (e.g., projection lenses).

In order to achieve these objectives as well as others that will become apparent with reference to the following specification, the present invention generally provides that multiple beams are used with lower energy than a single beam and impinges on the sample to increase in the effective pulse duration and initially heat the sample to allow larger grains to grow.

In one exemplary embodiment of the present invention, a process and system for processing a thin film sample is provided. In particular, a plurality of separated beams are generated, with each beam including beam pulses. At least one first beam of the separated beams is forwarded to irradiate and heat the thin film sample prior to further irradiation. Then at least one second beam of the separated beams is forwarded to further irradiate the thin film sample. At least one third beam of the separated beams is forwarded through the mask to further irradiate the thin film until the combined intensity of the beams impinging on the sample is sufficient to melt a section of the thin film throughout its entire thickness.

In a further exemplary embodiment, additional separated beams are forwarded through the mask to further irradiate a section of the thin film. During the irradiation of the section of the thin film by the masked beams the combined intensity is sufficient to melt the irradiated section of the thin film throughout an entire thickness of the at least one section of the thin film.

In a further exemplary embodiment, the separated beams impinge on the thin film with a time delay, increasing the effective pulse duration and the irradiation of the beams on the sample.

In a further exemplary embodiment, the separated beams are forwarded through different optical paths to impinge and irradiate the thin film with a time delay, increasing the effective pulse duration and the irradiation of the beams on the sample.

In another exemplary embodiment, the plurality of separated beams are generated by separate beam generating sources.

In another exemplary embodiment, the plurality of separated beams are generated from a single irradiation beam that passes through a splitter to become a plurality of separated beams. The beam splitter is preferably located upstream in a path of the irradiation beam pulses from the mask, and separates the irradiation beam pulses into the first set of beam pulses and the second set of beam pulses prior to the irradiation beam pulses reaching the mask.

In a further exemplary embodiment, the plurality of separated beams have a corresponding intensity which is lower than an intensity required to damage or degrade the mask.

In a further exemplary embodiment, the separated beams have a corresponding intensity which is lower than an intensity required to melt the at least one section of the thin film throughout the entire thickness.

In another exemplary embodiment of the present invention, a plurality of separated beams are generated, with each beam including beam pulses. At least one first beam of the separated beams is forwarded through a mask to irradiate and heat the thin film sample prior to further irradiation. Then at least one second beam of the separated beams is forwarded through a mask to further irradiate the thin film sample. at least one third beam of the separated beams is forwarded through the mask to further irradiate the thin film until the combined intensity of the beams impinging on the sample is sufficient to melt a section of the thin film throughout its entire thickness. The irradiated and melted section of the thin film is then allowed to re-solidify and crystallize.

In a further exemplary embodiment, the thin film sample is microtranslated so the separated beams impinge at least one previously irradiated, fully melted, re-solidified and crystallized portion of the section of the thin film.

In a further exemplary embodiment, the thin film sample is translated so the separated beams impinge a further section of the thin film. In still a further exemplary embodiment, the further section of the thin film sample at least partially overlaps the irradiated and melted section that re-solidified and crystallized. In a further exemplary embodiment, the separated beams pulses and irradiate the previously irradiated section of the thin film and fully melt the section of the thin film

In a further embodiment, the mask may have a dot-like pattern such that dot portions of the pattern are the opaque regions of the mask which prevent the first set of beam pulses to irradiate there through. Also, the mask may have a line pattern such that line portions of the pattern are the opaque regions of the mask which prevent the first set of beam pulses to irradiate there through. Furthermore, the mask may have a transparent pattern such that transparent portions of the pattern do not include any opaque regions therein.

The accompanying drawings, which are incorporated and constitute part of this disclosure, illustrate a preferred embodiment of the invention and serve to explain the principles of the invention.

### BRIEF DESCRIPTION OF THE DRAWINGS

FIG. 1 is a schematic block diagram of a prior art 1:1 projection irradiation system;

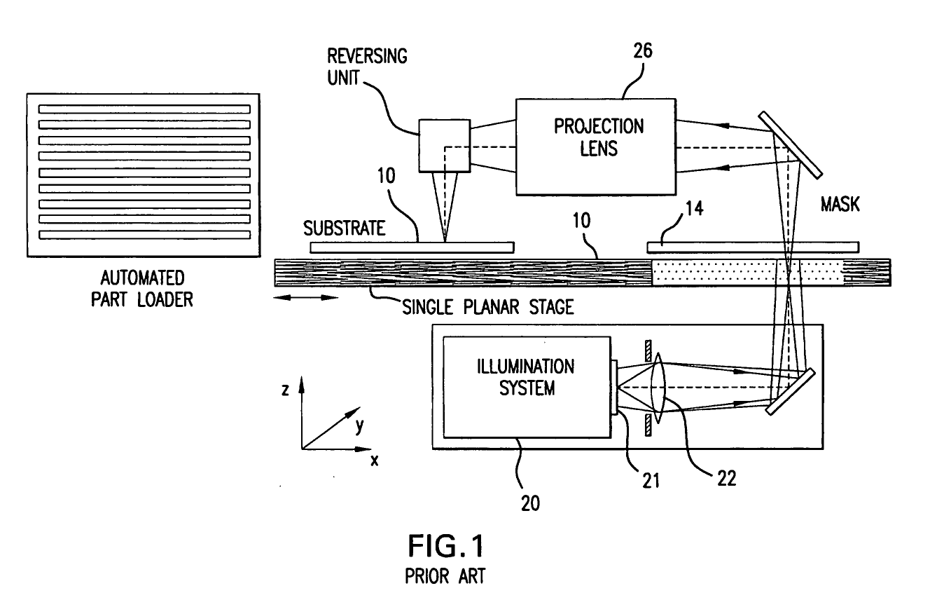

FIG. 2 is a schematic block diagram of an exemplary embodiment of a projection irradiation system according to the present invention;

FIG. 3 is a flow diagram representing an exemplary LS processing procedure under at least partial control of a computing arrangement of FIG. 2 using the processes of the present invention.

### DETAILED DESCRIPTION

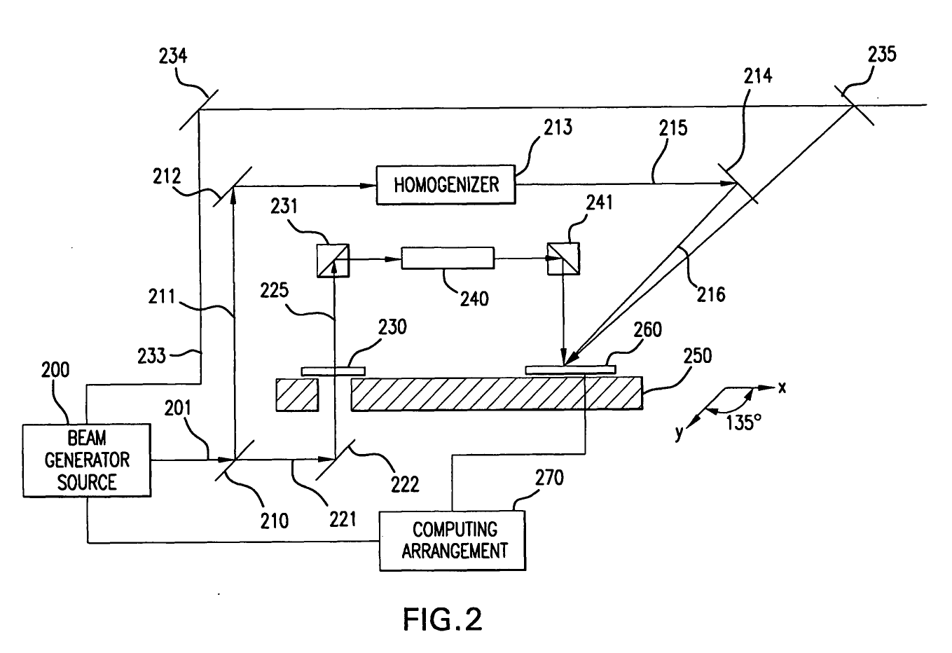

An exemplary embodiment of a projection irradiation system according to the present invention is shown as a schematic block diagram in FIG. 2. In particular, a beam source 200 (e.g., a pulsed excimer laser) generates an excimer laser beam 201 which passes through a beam splitter 210 to become a plurality of beams. In one exemplary implementation of the present invention, these the beam is split into three separate beams 211, 221, 233, where each has a lower energy than that of the original beam 201. Each of the beams 211, 221, 233 is composed of a set of beam pulses. It is within the scope of the present invention to possibly utilize other energy combinations with the exemplary system of the present invention illustrated in FIG. 2. It is also within the scope of the invention to use three beam sources or in the alternative to use a combination of beam sources and splitters to achieve the desired number of beams each at a particular energy level.

The first split beam 233 can be redirected by a mirror 234 and subsequently redirected by a second mirror 235 so as to be incident on a semiconductor sample 260, which is held by a sample translation stage 250, prior to further irradiation. The sample can be irradiated for any amount of time to heat the sample prior to further irradiation. It should be noted that samples, such as metallic, dielectric, or polymeric films may be used as well as a silicon semiconductor sample 260.

The second split beam 211 can be redirected by a mirror 212 toward a homogenizer 213, which then outputs a homogenized beam 215. Thereafter, the homogenized beam 215 (and its respective beam pulses) can be redirected by a second mirror 214 so as to be incident on a semiconductor sample 260 which is held by a sample translation stage 250. It should be noted that samples, such as metallic, dielectric, or polymeric films may be used as well as a silicon semiconductor sample 260.

During a substantially same time interval, the third split beam 221 (and its respective pulses) can be redirected by a mirror 222 to pass through a mask 230. The mirror is arranged such that the third split beam 221 is aligned with the mask 230 to allow the third split beam 221 (and its pulses) to be irradiated there through and become masked beam pulses 225. The masked beam pulses 225 can then be redirected by a second mirror 231 to pass through a projection lens 240. Thereafter, the masked beam pulses 225 which passed through the projection lens 240 are again redirected to a reversing unit 241 so as to be incident on the semiconductor sample 260. The mask 230, the projection lens 240 and the reversing unit 241 may be substantially similar or same as those described in the above-identified '236 patent. While other optical combinations may be used, the splitting of the original beam 201 should preferably occur prior to the original beam 201 (and its beam pulses) being passed through the mask 230.

It should be understood by those skilled in the art that instead of a pulsed excimer laser source, the beam source 200 may be another known source of short energy pulses suitable for melting a thin silicon film layer in the manner described herein below, such as a pulsed solid state laser, a chopped continuous wave laser, a pulsed electron beam or a pulsed ion beam, etc., with appropriate modifications to the radiation beam path from the source 200 to the sample 260. The translations and microtranslations of the sample stage 250 are preferably controlled by a computing arrangement 270, which is coupled to the beam source 200 and the sample stage 250. It is also possible for the computing arrangement 270 to control the microtranslations of the mask 230 so as to shift the intensity pattern of the first and second beams 211, 221 with respect to the sample 260. Typically, the radiation beam pulses generated by the beam source 200 provide a beam intensity in the range of 10 mJ/cm² to 1J/cm², a pulse duration (FWHM) in the range of 10 to 103 nsec, and a pulse repetition rate in the range of 10 Hz to 104 Hz.

In another exemplary embodiment, the systems and methods described in the '954 Publication, the entire disclosure of which is incorporated herein by reference, and their utilization of microtranslations of a sample, which may have an amorphous silicon thin film provided thereon that can be irradiated by irradiation beam pulses so as to promote the sequential lateral solidification on the thin film, without the need to microtranslate the sample and/or the beam relative to one another to obtain a desired length of the grains contained in the irradiated and re-solidified areas of the sample may be used according to the present invention.

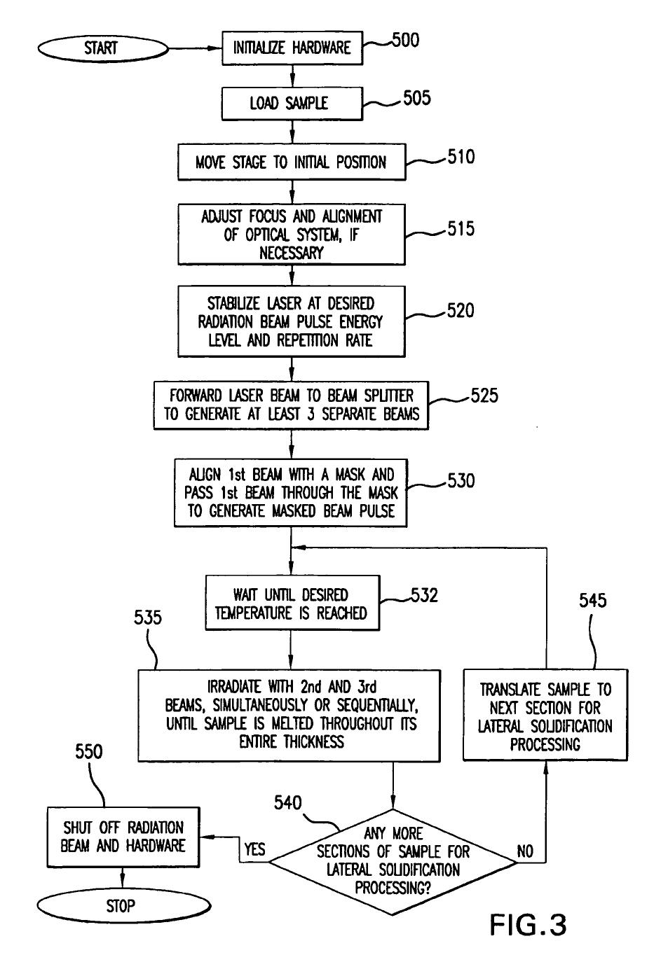

FIG. 3 is a flow diagram representing an exemplary LS processing procedure under at least partial computer control using the processes of the present invention, as may be carried out by the system of FIG. 2. In step 500, the hardware components of the system of FIG. 2, such as the beam source 200 and the homogenizer 213, are first initialized at least in part by the computing arrangement 270. The sample 260 is loaded onto the sample translation stage 250 in step 505. It should be noted that such loading may be performed either manually or automatically using known sample loading apparatus under the control of the computing arrangement 270. Next, the sample translation stage 250 is moved, preferably under the control of the computing arrangement 270, to an initial position in step 510. Various other optical components of the system are adjusted manually or under the control of the computing arrangement 270 for a proper focus and alignment in step 515, if necessary. In step 520, the irradiation/laser beam 201 is stabilized at a predetermined pulse energy level, pulse duration and repetition rate. Then, the irradiation/laser beam 201 is directed to the beam splitter 210 to generate the at least three separate beam pulses 211, 221, 233 in step 525. In step 530, the first split beam 233 is aligned with the mask 230, and the first split beam pulse 233 is irradiated through the mask 230 to form a masked beam pulse 225. In step 532, the beam impinges on the sample until the desired temperature is reached.

In step 535, the current section of the sample 260 is irradiated with the second beam 221 and the third beam 233, simultaneously or sequentially until the sample is completely melted throughout its entire thickness. During this step, the sample 260 can be microtranslated and the corresponding sections again irradiated and melted throughout their entire thickness. In step 540, it is determined whether there are any more sections of the sample 260 that need to be subjected to the LS processing. If so, the sample 260 is translated using the sample translation stage 250 so that the next section thereof is aligned with the first, second and third split beam pulses 211, 221, 233 (step 545), and the LS processing is returned to step 535 to be performed on the next section of the sample 260. Otherwise, the LS processing has been completed for the sample 260, the hardware components and the beam of the system shown in Figure can be shut off (step 550), and the process terminates.

The foregoing merely illustrates the principles of the invention. Various modifications and alterations to the described embodiments will be apparent to those skilled in the art in view of the teachings herein. For example, while the above embodiment has been described with respect to sequential lateral solidification, it may apply to other materials processing techniques, such as micro-machining, photo-ablation, and micro-patterning techniques, including those described in International patent application no. PCT/US01/12799 and U.S. patent application Ser. Nos. 09/390,535, 09/390,537 and 09/526,585, the entire disclosures of which are incorporated herein by reference. The various mask patterns and intensity beam patterns described in the above-referenced patent application can also be utilized with the process and system of the present invention. It will thus be appreciated that those skilled in the art will be able to devise numerous systems and methods which, although not explicitly shown or described herein, embody the principles of the invention and are thus within the spirit and scope of the invention.

What is claimed is:

1. A process for producing a thin film on a sample, comprising the steps of:
(a) generating a plurality of separated beams each including beam pulses;
(b) forwarding at least a portion of at least one first beam of the separated beams to irradiate and heat at least one section of the thin film prior to further irradiation of the at least one section of the thin film;
(c) forwarding at least a portion of at least one second beam of the separated beams to further irradiate the at least one section of the thin film; and
(d) forwarding at least a portion of at least one third beam of the separated beams through a mask to further irradiate the at least one section of the thin film wherein, during the irradiation of the at least one section of the thin film at least one irradiated section of the thin film is melted throughout an entire thickness of the at least one section of the thin film.

2. The process according to claim 1, further comprising forwarding at least a portion of at least a multiplicity of separated beams to further irradiate the at least one section of the thin film wherein, during the irradiation of the at least one section of the thin film by the multiplicity of beams the at least one irradiated section of the thin film is melted throughout an entire thickness of the at least one section of the thin film.

3. The process according to claim 1, wherein the separated beams are forwarded to impinge and irradiate the at least one section of the thin film at different times, wherein the effective pulse duration of the at least a portion of at least one second beam and the at least a portion of at least one third beam that impinge and irradiate the at least one section of the thin film is increased.

4. The process according to claim 1, wherein the beams are forwarded through different optical paths to impinge and irradiate the at least one section of the thin film at different times.

5. The process according to claim 1, wherein the plurality of separated beams are generated by separate beam generating sources.

6. The process according to claim 1, wherein at least the at least one third beam of the separated beams have a corresponding intensity which is lower than an intensity required to damage or degrade the mask.

7. The process according to claim 1, wherein the separated beams have a corresponding intensity which is lower than an intensity required to melt the at least one section of the silicon thin film throughout the entire thickness thereof.

8. The process according to claim 1, wherein, after step (d), the at least one irradiated and melted section of the thin film is allowed to re-solidify and crystallize.

9. The process according to claim 9, further comprising microtranslating the sample so that the separated beams impinge at least one previously irradiated, fully melted, re-solidified and crystallized portion of the section of the thin film.

10. The process according to claim 10, further comprising translating the thin film sample so that the separated beams impinge a further section of the thin film, wherein the further section of the thin film at least partially overlaps the irradiated and melted section that was allowed to re-solidify and crystallize.

11. The process according to claim 10, wherein the separated beams pulses irradiate the at least one previously irradiated section of the thin film and fully melt the section of the thin film.

12. The process according to claim 1, wherein the at least one first beam of the separated beams is passed through a mask to further irradiate the at least one section of the thin film.

13. The process according to claim 1, wherein the at least one second beam of the separated beams is passed through a mask to further irradiate the at least one section of the thin film.

14. The process according to claim 1, wherein the mask has a dot-like pattern such that dot portions of the pattern are opaque regions of the mask which prevent certain portions of the separated beams to irradiate there through.

15. The process according to claim 1, wherein the mask has a line pattern such that line portions of the pattern are opaque regions of the mask which prevent certain portions of the separated beams to irradiate there through.

16. The process according to claim 1, wherein the mask has a transparent pattern such that transparent portions of the pattern do not include opaque regions therein, the opaque regions capable of preventing certain portions of the separated beams to irradiate there through.

17. A system for processing a thin film on a sample, comprising:
a memory storing a computer program; and
a processing arrangement executing the computer program to perform the following steps:
(a) controlling an irradiation beam generator to generate a plurality of separated beams;
(b) forwarding at least a portion of at least one first beam of the separated beams to irradiate and heat at least one section of the thin film prior to further irradiation of the at least one section of the thin film;
(c) forwarding at least a portion of at least one second beam of the separated beams to further irradiate the at least one section of the thin film; and
(d) forwarding at least a portion of at least one third beam of the separated beams through a mask to further irradiate the at least one section of the thin film
wherein, during the irradiation of the at least one section of the thin the at least one irradiated section of the thin film is melted throughout an entire thickness of the at least one section of the thin film.

18. The system according to claim 17, further comprising a beam splitter arranged in a vicinity of the processing arrangement, wherein the processing arrangement causes the irradiation beam to be forwarded to the beam splitter which separates the irradiation beam into a plurality of separated beams.

19. The system according to claim 18, wherein the beam splitter is located upstream in a path of the irradiation beams from the mask.

20. The system according to claim 17, wherein at least the at least one third beam of the separated beams has a corresponding intensity which is lower than an intensity required to damage or degrade the mask.

21. The system according to claim 17, wherein the processing arrangement executes the computer program to forward the at least one first beam of the separated beam pulses through a mask.

22. The system according to claim 17, wherein the processing arrangement executes the computer program to forward the at least one second beam of the separated beam pulses through a mask.

23. The system according to claim 17, wherein the third set of separated beams has a corresponding intensity which is lower than an intensity required to melt the at least one section of the silicon thin film throughout the entire thickness thereof.

24. The system according to claim 17, wherein, when at least one section of the silicon thin film is irradiated, the at least one irradiated and melted section of the silicon thin film is allowed to re-solidify and crystallize.

25. The system according to claim 17, wherein, during step (d), the at least one irradiated and melted section of the thin film is allowed to re-solidify and crystallize.

26. The system according to claim 25, further comprising microtranslating the sample so that the separated beams impinge at least one previously irradiated, fully melted, re-solidified and crystallized portion of the section of the thin film.

27. The system according to claim 26, further comprising translating the thin film sample so that the separated beams impinge a further section of the thin film, wherein the further section of the thin film at least partially overlaps the irradiated and melted section that was allowed to re-solidify and crystallize.

28. The system according to claim 26, wherein the separated beams pulses and irradiate the at least one previously irradiated section of the thin film and fully melt the section of the thin film.

29. The system according to claim 17, wherein the mask has a dot-like pattern such that dot portions of the pattern are opaque regions of the mask which prevent certain portions of the separated beams to irradiate there through.

30. The system according to claim 17, wherein the mask has a line pattern such that line portions of the pattern are opaque regions of the mask which prevent certain portions of the separated beams to irradiate there through.

31. The system according to claim 17, wherein the mask has a transparent pattern such that transparent portions of the pattern do not include opaque regions therein, the opaque regions capable of preventing certain portions of the separated beams to irradiate there through.
